(19) United States
(12) Patent Application Publication
(10) Pub. No.: US 2021/0385969 A1
(43) Pub. Date: Dec. 9, 2021

(54) WATER-COOLING GRID

(71) Applicant: Shenzhen Sixty-six Technology Co.,Ltd, Shenzhen (CN)

(72) Inventor: Xiantao Geng, Shenzhen (CN)

(21) Appl. No.: 17/213,228

(22) Filed: Mar. 26, 2021

(30) Foreign Application Priority Data
Jun. 9, 2020 (CN) 202021043712.9
Mar. 4, 2021 (CN) 202120467569.4

(51) Int. Cl. H05K 7/20; G06F 1/20

(52) U.S. Cl. CPC H05K 7/20263; G06F 2200/201; H05K 7/20272; G06F 1/20

(57) ABSTRACT

The utility model discloses a water-cooling grid, and relates to the technical field of radiators. The water-cooling grid includes a water pump component, a first liquid pipe, a lower water tank, an upper water tank, second liquid pipes and fins. The utility model mainly solves the problem that a water-cooling head is extremely large in volume, and can effectively reduce the volume of the water-cooling head and avoid occupation of the space.

### CROSS-REFERENCE TO RELATED APPLICATIONS

This application claims priority to Chinese Patent Application No. 202021043712.9 with a filing date of Jun. 9, 2020 and Chinese Patent Application No. 202120467569.4 with a filing date of Mar. 4, 2021. The content of the aforementioned applications, including any intervening amendments thereto, are incorporated herein by reference.

### TECHNICAL FIELD

The utility model relates to the technical field of radiators, and specifically relates to a water-cooling grid.

### BACKGROUND

Commonly used desktop computers usually include a mainframe, display equipment, and peripherals. The mainframe is developing towards miniaturization. Therefore, the space in a case of the mainframe is constantly being compressed. At the same time, users expect that the computer can provide more powerful computing power and graphics performance. For this reason, a central processing unit (CPU) serving as a computing core and a graphics processing unit (GPU) for processing image operation work generate more and more heat. As a high-efficiency radiator for the CPU and the GPU, a water-cooling radiator is increasingly used in mainframes.

The water-cooling radiator includes a water-cooling head and a water-cooling grid, which are connected by a water pipe. A water pump of the water-cooling radiator is arranged at the water-cooling head, so that the water-cooling head is extremely large in volume and easily occupies the space of a main board.

### SUMMARY

The utility model is directed to provide a water-cooling grid which is provided with a water pump and can reduce the volume of a water-cooling head cooperating therewith.

In order to achieve the above objective, the utility model provides the following technical solution: A water-cooling grid includes a water pump component, a first liquid pipe, and a lower water tank and an upper water tank which are opposite to each other, a plurality of second liquid pipes and a plurality of fins. The upper water tank includes a water tank bottom plate and a main box body; the main box body is arranged on the water tank bottom plate; a side of the water tank bottom plate extends out to form an extending platform; the water pump component is arranged on the extending platform; one end of each second liquid pipe penetrates into the lower water tank, and the other end of the second liquid pipe penetrates into the water tank bottom plate of the upper water tank and enters the main box body, so as to communicate the lower water tank with the upper water tank; a first end of the first liquid pipe is connected into the lower water tank; a second end of the first liquid pipe communicates with a water inlet end of the water pump component; a water outlet end of the water pump component is provided with another fast connecting head used for communicating with the water-cooling head; the fins are arranged between each pair of adjacent second liquid pipes in an interpenetrating manner; and the fins are also arranged between the first liquid pipe and the adjacent second liquid pipe in an interpenetrating manner.

In the above technical solution, a connecting seat is arranged on the extending platform of the upper water tank; the second end of the first liquid pipe penetrates through the extending platform; the connecting seat covers the second end of the first liquid pipe; the water pump component is fixed on the connecting seat; a communicating hole running through upper and lower surfaces of the connecting seat is formed in the connecting seat; and the communicating hole communicates with the second end of the first liquid pipe and the water inlet end of the water pump component.

In the above technical solution, the water pump component includes a bottom plate, an upper shell, an impeller, a coil and a rotating shaft; a rotating shaft slot is formed in the center of the inner side of the upper shell, and a guide slot is formed in the edge; an accommodating cavity is formed between the rotating shaft slot and the guide slot on the outer side of the upper shell; the slot bottom of the rotating shaft slot is formed into an upper rotating shaft seat; the bottom plate is formed into a lower rotating shaft seat; the bottom plate and the upper shell are combined, and the lower rotating shaft seat is opposite to the upper rotating shaft seat; two ends of the rotating shaft are respectively inserted into the upper rotating shaft seat and the lower rotating shaft seat; a periphery of the impeller is formed into a guide ring; the impeller is accommodated between the bottom plate and the upper shell, and is sleeved on the rotating shaft; the guide ring is located in the guide slot; the coil is accommodated in the accommodating cavity on the outer side of the upper shell; the coil is magnetically coupled to drive the impeller to rotate; the water inlet end penetrates through the bottom plate; the water outlet end is located on the side surface of the upper shell; the upper shell is fixed on the connecting seat; and the bottom plate covers the communicating hole of the connecting seat.

In the above technical solution, a shaft sleeve is arranged between the rotating shaft and the impeller.

In the above technical solution, a sealing ring is arranged between the upper shell and the connecting seat.

In the above technical solution, a first lower liquid pipe hole matching the shape of the first liquid pipe is formed in the lower water tank, and a first upper liquid pipe hole matching the shape of the first liquid pipe is formed in the extending platform of the water tank bottom plate of the upper water tank; the first end of the first liquid pipe penetrates into the first lower liquid pipe hole; the second end of the first liquid pipe penetrates into the first upper liquid pipe hole; the lower water tank is provided with, at intervals, second lower liquid pipe holes matching the shapes of the second liquid pipes and corresponding to the second liquid pipes in the quantity; the water tank bottom plate of the upper water tank is provided with, at intervals, second upper liquid pipe holes matching the shapes of the second liquid pipes and corresponding to the second liquid pipes in the quantity; and two ends of the second liquid pipes are correspondingly inserted into the second lower liquid pipe holes and the second upper liquid pipe holes respectively.

In the above technical solution, the water-cooling grid further includes fasteners used for fastening the first liquid pipe, the second liquid pipes and the fins.

In the above technical solution, the water-cooling grid further includes a housing that encircles the water pump component and the upper water tank, and the fast connecting head penetrates through the housing.

Compared with the prior art, the utility model has the beneficial effects that: The water-cooling grid includes the water pump component, so that water-cooling fluid is driven by means of the water pump component to be circulated between the water-cooling head and the water-cooling grid; and the water pump component is arranged on the water-cooling grid, so that the water pump component and the water-cooling grid are integrated, the volume of the water-cooling head can be effectively reduced, and occupation of the space of the main board is avoided.

The utility model discloses a water-cooling grid, and relates to the technical field of radiators. The water-cooling grid includes a water pump component, a first liquid pipe, a lower water tank, an upper water tank, second liquid pipes and fins. The upper water tank includes a water tank bottom plate and a main box body; the main box body is arranged on the water tank bottom plate; a side of the water tank bottom plate extends out to form an extending platform; the water pump component is arranged on the extending platform; one end of each second liquid pipe penetrates into the lower water tank, and the other end of the second liquid pipe penetrates into the water tank bottom plate of the upper water tank and enters the main box body, so as to communicate the lower water tank with the upper water tank; a first end of the first liquid pipe is connected into the lower water tank; a second end of the first liquid pipe communicates with a water inlet end of the water pump component; a water outlet end of the water pump component is provided with another fast connecting head used for communicating with the water-cooling head; the fins are arranged between each pair of adjacent second liquid pipes in an interpenetrating manner; and the fins are also arranged between the first liquid pipe and the adjacent second liquid pipe in an interpenetrating manner. The utility model mainly solves the problem that a water-cooling head is extremely large in volume, and can effectively reduce the volume of the water-cooling head and avoid occupation of the space.

### BRIEF DESCRIPTION OF THE DRAWINGS

FIG. 1 is a stereoscopic view of the utility model;

FIG. 2 is an exploded view of the utility model;

FIG. 3 is an exploded view of a water pump component in the utility model;

FIG. 4 is a sectional view of a water pump component in the utility model; and

FIG. 5 is a sectional view of the utility model.

FIG. 6 is a schematic diagram of cooperative use with a water-cooling head of the utility model.

Numerals in the drawings: 1: water pump component; 11: bottom plate; 111: water outlet end; 12: lower rotating shaft seat; 121: opening; 13: upper shell; 131: rotating shaft slot; 132: upper rotating shaft seat; 133: guide slot; 134: accommodating cavity; 135: water outlet end; 14: impeller; 141: blade; 142: guide ring; 15: coil; 16: sealing ring; 17: rotating shaft; 18: shaft sleeve; 2: lower water tank; 21: first lower liquid pipe hole; 22: second lower liquid pipe hole; 3: upper water tank; 31: water tank bottom plate; 311: second upper liquid pipe hole; 312: extending platform; 313: first upper liquid pipe hole; 32: main box body; 4: first liquid pipe; 41: first end; 42: second end; 5: second liquid pipe; 6: fin; 7: fast connecting head; 8: fastener; 9: housing; 101: water pipe; 102: water-cooling head.

### DESCRIPTION OF THE EMBODIMENTS

The technical solutions in the embodiments of the present utility model will be described clearly and completely below with reference to the drawings in the embodiments of the present utility model. Obviously, the embodiments described herein are only part of the embodiments of the present utility model, not all the embodiments. Based on the embodiments in the utility model, all other embodiments obtained by those of ordinary skill in the art without creative work shall fall within the protection scope of the utility model.

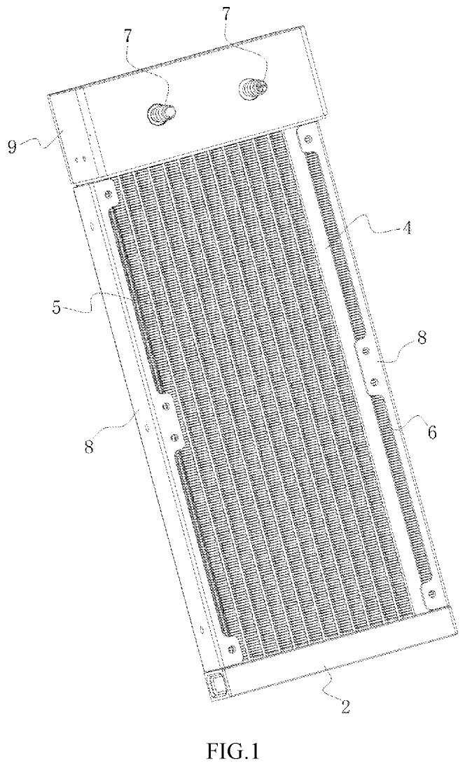

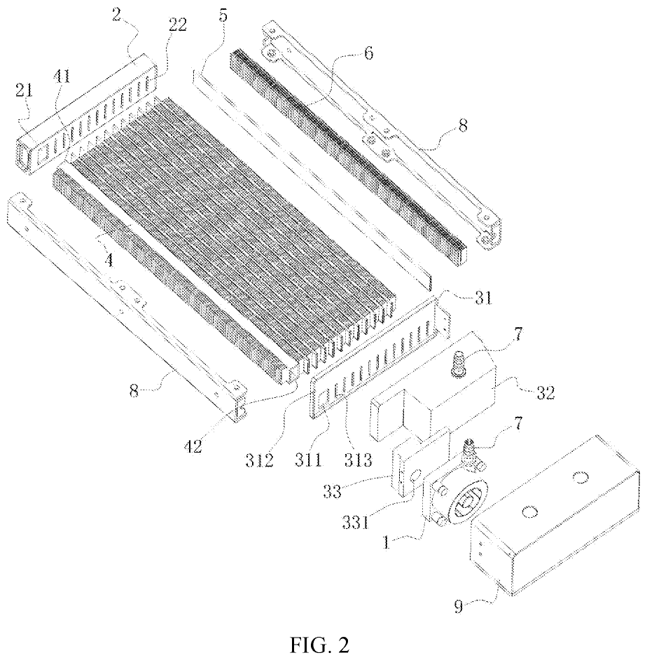

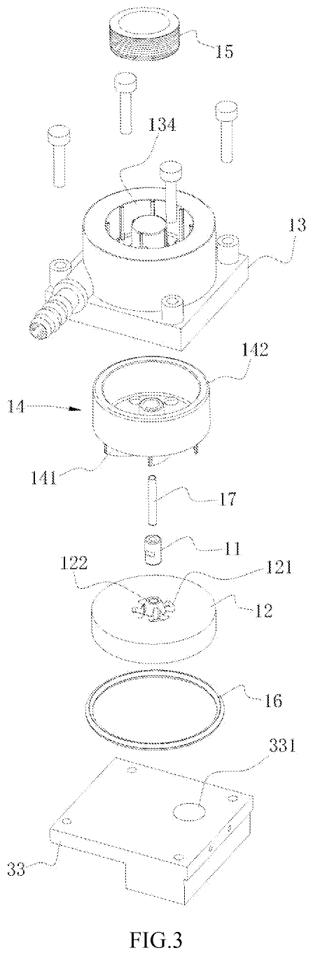

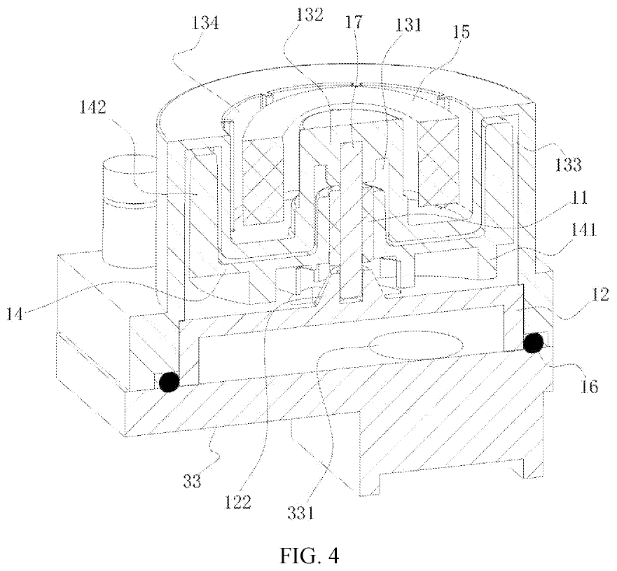

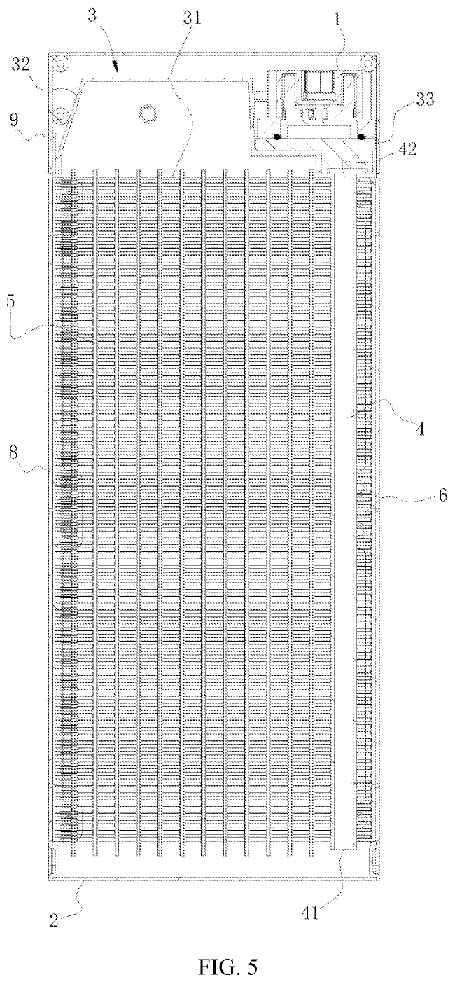

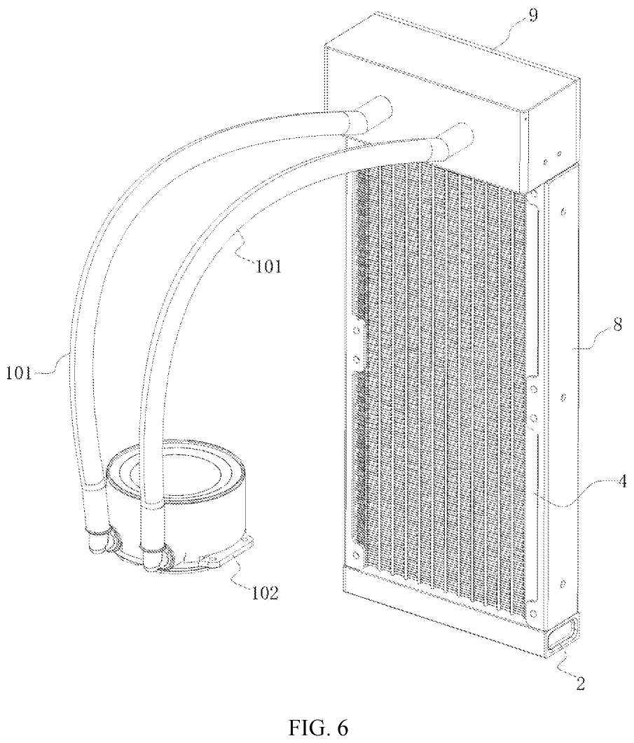

Referring to FIG. 1 to FIG. 6, a water-cooling grid includes a water pump component 1, a first liquid pipe 4, and a lower water tank 2 and an upper water tank 3 which are opposite to each other, a plurality of second liquid pipes 5 and a plurality of fins 6. The upper water tank 3 includes a water tank bottom plate 31 and a main box body 32; the main box body 32 is arranged on the water tank bottom plate 31; a side of the water tank bottom plate 31 extends out to form an extending platform 312; the water pump component 1 is arranged on the extending platform 312; one end of each second liquid pipe 5 penetrates into the lower water tank 2, and the other end of the second liquid pipe 5 penetrates into the water tank bottom plate 31 of the upper water tank 3 and enters the main box body 32, so as to communicate the lower water tank 2 with the upper water tank 3; a first end 41 of the first liquid pipe 4 is connected into the lower water tank 2; a second end 42 of the first liquid pipe 4 communicates with a water inlet end 111 of the water pump component 1; a water outlet end 135 of the water pump component 1 is provided with another fast connecting head 7 used for communicating with the water-cooling head; the fins 6 are arranged between each pair of adjacent second liquid pipes 5 in an interpenetrating manner; and the fins 6 are also arranged between the first liquid pipe 4 and the adjacent second liquid pipe 5 in an interpenetrating manner.

In the present embodiment, the first liquid pipe 4 is located at an extreme edge, and the outer side is provided with the fins 6. The outer side of one second liquid pipe 5 located at the extreme edge is also provided with the fins 6.

The water tank bottom plate 31 is an aluminum alloy flat plate; the main box body 32 is a half box body made of aluminum alloy; the main box body 32 is welded on the water tank bottom plate 31 to form a sealed upper water tank 3; the lower water tank 2 is a square aluminum alloy box body; the first liquid pipe 4 and the second liquid pipes 5 are aluminum alloy pipes; a sectional area of the first liquid pipe 4 is larger than the sectional area of each second liquid pipe 5; the fluid flow velocity that the first liquid pipe 4 can withstand is the sum of the fluid flow velocities of all the second liquid pipes 5; the fins 6 are aluminum alloy sheets, and are bent to form drapes to enlarge a contact area with air; and the fast connecting head 7 is a tubular workpiece made of an engineering plastic material.

A connecting seat 33 is arranged on the extending platform 312 of the upper water tank 3; the connecting seat 33 is an aluminum alloy plate; the second end 42 of the first liquid pipe 4 penetrates through the extending platform 312; the connecting seat 33 covers the second end 42 of the first liquid pipe 4; the water pump component 1 is fixed on the connecting seat 33; a communicating hole 331 running through upper and lower surfaces of the connecting seat is formed in the connecting seat 33; and the communicating hole 331 communicates with the second end 42 of the first liquid pipe 4 and the water inlet end 121 of the water pump component 1.

Specifically, the water pump component 1 includes a bottom plate 11, an upper shell 13, an impeller 14, a coil 15 and a rotating shaft 17; the upper shell 13 is an engineering plastic workpiece; a cylindrical rotating shaft slot 131 is formed in the center of the inner side of the upper shell 13, and a circular-ring-shaped guide slot 133 is formed in the edge of the upper shell 13; a circular-ring-shaped accommodating cavity 134 is formed between the rotating shaft slot 131 and the guide slot 133 on the outer side of the upper shell 13; the slot bottom of the rotating shaft slot 131 is formed into an upper rotating shaft seat 132; the upper rotating shaft seat 132 is provided with an insertion hole for allowing one end of the rotating shaft 17 to be inserted; the bottom plate 11 is a platy piece made of an engineering plastic material; the bottom plate 11 is formed into a lower rotating shaft seat 12; an insertion hole for allowing the other end of the rotating shaft 17 to be inserted is formed in the center of the lower rotating shaft seat 12; and the bottom plate 11 is combined with the upper shell 13. In the present embodiment, an outer edge of the bottom plate 11 is attached to an inner wall of the upper shell 13; and the lower rotating shaft seat 12 is opposite to the upper rotating shaft seat 132 in the upper shell 13. Specifically, the insertion hole of the lower rotating shaft seat 12 is opposite to the insertion hole of the upper rotating shaft seat 132. The rotating shaft 17 is a metal shaft, and two ends of the rotating shaft 17 are respectively inserted into the upper rotating shaft seat 132 and the lower rotating shaft seat 12. The impeller 14 is a workpiece made of a plastic-magnetic material. The impeller 14 is magnetic after being magnetized; a plurality of blades 141 are arranged on a body of the impeller 14; a through hole axially running through the impeller 14 is formed in the center of the body of the impeller 14; a periphery of the impeller 14 is formed into an annular guide ring 142; the guide ring 142 can match the guide slot 133 of the upper shell 13; the impeller 14 is accommodated between the bottom plate 11 and the upper shell 13 and is sleeved on the rotating shaft 17; and the guide ring 142 is located in the guide slot 133. The coil 15 is an electromagnetic coil, and can generate a rotary magnetic field after being electrified. The coil 15 is accommodated in the accommodating cavity 134 on the outer side of the upper shell 13. The coil 15 is magnetically coupled to drive the impeller 14 to rotate; and the water inlet end 121 of the water pump component 1 runs through the bottom plate 11. In the present embodiment, the water inlet end 121 of the water pump component 1 surrounds the lower rotating shaft seat 12, and the water outlet end 135 of the water pump component 1 is located on the side surface of the upper shell 13; and the upper shell 13 is fixed on the connecting seat 33. In the present embodiment, a screw hole is formed in the connecting seat 33; a screw is locked into the screw hole of the connecting seat 33 after passing through the upper shell 13, thus fixing the upper shell 13 and then fixing the whole water pump component 1. The bottom plate 11 covers the communicating hole 331 of the connecting seat 33.

After assembling, when the coil 15 is electrified, the rotary magnetic field would be generated. The rotary magnetic field is magnetically coupled to the impeller 14 to drive the impeller 14 to rotate. When rotating, the impeller 14 can drive liquid in the water pump component 1 to flow to suck the liquid into the water inlet end 111 and push the liquid out from the water outlet end 135.

Further, a shaft sleeve 18 is arranged between the rotating shaft 17 and the impeller 14. In the present embodiment, the shaft sleeve 11 is a ceramic shaft sleeve. The shaft sleeve 11 is disposed to cause the impeller 14 to rotate more smoothly around the rotating shaft 17.

Further, a sealing ring 16 is arranged between the upper shell 13 and the connecting seat 33. In the present embodiment, the sealing ring 16 is a circular-ring-shaped rubber sealing ring. The sealing ring 16 is disposed to enhance the sealing between the upper shell 13 and the connecting seat 33.

Further, a first lower liquid pipe hole 21 matching the shape of the first liquid pipe 4 is formed in the lower water tank 2, and a first upper liquid pipe hole 313 matching the shape of the first liquid pipe 4 is formed in the extending platform 312 of the water tank bottom plate 31 of the upper water tank 3; the first end 41 of the first liquid pipe 4 penetrates into the first lower liquid pipe hole 21; the second end 42 of the first liquid pipe 4 penetrates into the first upper liquid pipe hole 313; after the water pump component 1 is fixed on the extending platform 312, the water inlet end 111 of the water pump component 1 covers the second end 42 of the first liquid pipe 4, so that the second end 42 of the first liquid pipe 4 communicates to the water inlet end 111 of the water pump component 1; the lower water tank 2 is provided with, at intervals, second lower liquid pipe holes 22 matching the shapes of the second liquid pipes 5 and corresponding to the second liquid pipes in the quantity; the water tank bottom plate 31 of the upper water tank 3 is provided with, at intervals, second upper liquid pipe holes 311 matching the shapes of the second liquid pipes 5 and corresponding to the second liquid pipes in the quantity; and two ends of the second liquid pipes 5 are correspondingly inserted into the second lower liquid pipe holes 22 and the second upper liquid pipe holes 311 respectively.

Further, the water-cooling grid further includes fasteners 8 used for fastening the first liquid pipe 4, the second liquid pipe 5 and the fins 6. Specifically, there are two fasteners 8. The two fasteners 8 press the first liquid pipe 4, the second liquid pipe 5 and the fins 6 respectively from the left and right sides, and are fixedly connected to the fins 6 on the outermost side respectively through screws.

Further, the water-cooling grid further includes a housing 9 surrounding the water pump component 1 and the upper water tank 3. The fast connecting head 7 passes through the housing 9, and are thus respectively connected to the water pump component 1 and the upper water tank 3.

After the lower water tank 2, the upper water tank 3, the first liquid pipe 4, the second liquid pipes 5, the fins 6, the fasteners 8 and the connecting seat 33 are assembled, the fasteners 8 are pressed from two sides through a clamp, thereby pressing the first liquid pipe 4, the second liquid pipes 5 and the fins 6; and the whole passes through a brazier to cause the lower water tank 2, the upper water tank 3, the first liquid pipe 4, the second liquid pipes 5, the fins 6, the fasteners 8 and the connecting seat 33 to be integrated.

During use of the water-cooling grid, two fast connecting heads 7 are connected to a water-cooling head 102 through water pipes 101; after the water pump component 1 is initiated, water-cooling fluid is driven to pass through the water outlet end 135 of the water pump component 1, one of the water pipes 101, the water-cooling head 102, the other water pipe 101, the upper water tank 3, all the second liquid pipes 5, the lower water tank 2 and the first liquid pipe 4, and then finally flows back to the water inlet end 111 of the water pump component 1. When passing through the water-cooling head, the water-cooling fluid absorbs heat of a CPU or GPU; when passing through the first liquid pipe 4 and the second liquid pipes 5, the heat is dissipated through the first liquid pipe 4, the second liquid pipes 5 and the fins 6; and the effect is better if a fan is mounted on the water-cooling grid.

Although the embodiments of the utility model have been shown and described, it will be understood by those of ordinary skill in the art that various changes, modifications, substitutions, and transformations can be made to these embodiments without departing from the principle and spirit of the utility model. The scope of the utility model is defined by the attached claims and their equivalents.

What is claimed is:

1. A water-cooling grid, comprising a water pump component, a first liquid pipe, and a lower water tank and an upper water tank which are opposite to each other, a plurality of second liquid pipes and a plurality of fins, wherein
the upper water tank comprises a water tank bottom plate and a main box body; the main box body is arranged on the water tank bottom plate; a side of the water tank bottom plate extends out to form an extending platform; the water pump component is arranged on the extending platform;
one end of each second liquid pipe penetrates into the lower water tank, and the other end of the second liquid pipe penetrates into the water tank bottom plate of the upper water tank and enters the main box body, so as to communicate the lower water tank with the upper water tank;
a first end of the first liquid pipe is connected into the lower water tank; a second end of the first liquid pipe communicates with a water inlet end of the water pump component; a water outlet end of the water pump component is provided with another fast connecting head used for communicating with the water-cooling head;
the fins are arranged between each pair of adjacent second liquid pipes in an interpenetrating manner; and the fins are also arranged between the first liquid pipe and the adjacent second liquid pipe in an interpenetrating manner.

2. The water-cooling grid according to claim 1, wherein a connecting seat is arranged on the extending platform of the upper water tank; the second end of the first liquid pipe penetrates through the extending platform; the connecting seat covers the second end of the first liquid pipe; the water pump component is fixed on the connecting seat;
a communicating hole running through upper and lower surfaces of the connecting seat is formed in the connecting seat; and the communicating hole communicates with the second end of the first liquid pipe and the water inlet end of the water pump component.

3. The water-cooling grid according to claim 2, wherein the water pump component comprises a bottom plate, an upper shell, an impeller, a coil and a rotating shaft;
a rotating shaft slot is formed in the center of the inner side of the upper shell, and a guide slot is formed in the edge; an accommodating cavity is formed between the rotating shaft slot and the guide slot on the outer side of the upper shell; the slot bottom of the rotating shaft slot is formed into an upper rotating shaft seat;
the bottom plate is formed into a lower rotating shaft seat; the bottom plate and the upper shell are combined, and the lower rotating shaft seat is opposite to the upper rotating shaft seat; two ends of the rotating shaft are respectively inserted into the upper rotating shaft seat and the lower rotating shaft seat;
a periphery of the impeller is formed into a guide ring; the impeller is accommodated between the bottom plate and the upper shell, and is sleeved on the rotating shaft; the guide ring is located in the guide slot; the coil is accommodated in the accommodating cavity on the outer side of the upper shell; the coil is magnetically coupled to drive the impeller to rotate;
the water inlet end penetrates through the bottom plate; the water outlet end is located on the side surface of the upper shell; the upper shell is fixed on the connecting seat; and the bottom plate covers the communicating hole of the connecting seat.

4. The water-cooling grid according to claim 3, wherein a shaft sleeve is arranged between the rotating shaft and the impeller.

5. The water-cooling grid according to claim 3, wherein a sealing ring is arranged between the upper shell and the connecting seat.

6. The water-cooling grid according to claim 1, wherein a first lower liquid pipe hole matching the shape of the first liquid pipe is formed in the lower water tank, and a first upper liquid pipe hole matching the shape of the first liquid pipe is formed in the extending platform of the water tank bottom plate of the upper water tank; the first end of the first liquid pipe penetrates into the first lower liquid pipe hole; the second end of the first liquid pipe penetrates into the first upper liquid pipe hole;
the lower water tank is provided with, at intervals, second lower liquid pipe holes matching the shapes of the second liquid pipes and corresponding to the second liquid pipes in the quantity; the water tank bottom plate of the upper water tank is provided with, at intervals, second upper liquid pipe holes matching the shapes of the second liquid pipes and corresponding to the second liquid pipes in the quantity; and two ends of the second liquid pipes are correspondingly inserted into the second lower liquid pipe holes and the second upper liquid pipe holes respectively.

7. The water-cooling grid according to claim 1, further comprising fasteners used for fastening the first liquid pipe, the second liquid pipes and the fins.

8. The water-cooling grid according to claim 1, further comprising a housing that encircles the water pump component and the upper water tank, wherein the fast connecting head penetrates through the housing.
